(19) United States
(12) Patent Application Publication
(10) Pub. No.: US 2020/0253379 A1
(43) Pub. Date: Aug. 13, 2020

(54) METHOD AND SYSTEM FOR CONTROLLING AN ACTUATOR

(71) Applicant: InSeat Solutions, LLC, La Verne, CA (US)

(72) Inventor: Wenbin Song, Walnut, CA (US)

(21) Appl. No.: 16/272,839

(22) Filed: Feb. 11, 2019

(51) Int. Cl. A47C 1/032; H03G 3/24; A47C 31/00

(52) U.S. Cl. CPC A47C 1/03211; A47C 31/008; A47C 1/03294; H03G 3/24

(57) ABSTRACT

A system and computer implemented method for controlling an actuator in a reclining seat. A plurality of actuators are provided in a reclining seat, each actuator moving at least one portion of the reclining seat. Voltage spike pulses are generated as each actuator moves the at least one portion of the reclining seat. Voltage spike pulses of each actuator motor are counted as each actuator moves, and a configuration of the reclining seat is stored in a memory associated with the reclining seat.

### BACKGROUND

The present disclosure relates to reclining seats. More particularly, the present disclosure is directed to a method and system for controlling an actuator motor of a reclining seat.

There are more and more reclining seats where movement of the reclining seat between various positions is electronically-controlled. A reclining seat can be built with one or more actuator motors. Each actuator motor can move one or more portions of the reclining seat between stowed and deployed positions. These portions of the reclining seat include, without limitation, a seat back, a leg rest, a head rest, and a lumbar support. A actuator motor can also be used to vertically lift and lower the reclining seat itself. An electronically-controlled reclining seat can come with a control wand. The control wand can include buttons for operation of the actuator motors in disposed within the reclining seat. For example, the control wand can include buttons for moving one or more portions of the reclining seat between stowed and deployed positions including, without limitation, the seat back, the leg rest, the head rest, the lumbar support, as well as a button for adjusting the vertical position of the reclining seat itself. These buttons can include, without limitation, a back up/down button, a leg up/down button, a head up/down button, a lumbar out/in button, and a recline/return button. The control wand can also include memory buttons, which memorize the favorite seat position of one or more users (e.g., a particular configuration of the reclining seat where each of the portions of the reclining seat are in a particular position is stored in a memory associated with the control wand). Upon pressing a particular memory button, one or more of the actuator motors moves the reclining seat into the particular configuration stored in a memory associated with the control wand. The particular configuration is composed of each of the various moveable portions of the reclining seat being disposed in a particular position.

Currently, there are two methods for memory control of actuator motors used in electrically-controlled reclining seats found in the marketplace: counting actuator motor running time; and monitoring an encoder found in an actuator motor. The first method of memory control involves counting actuator motor running time. This involves counting the time for every motor movement with positive time on one motor running direction and negative time on the other direction. This method calculates motor running time to define the actuator current position. To set a reclining seat to a particular memory position, an algorithm runs the actuator motor and calculates the motor running time to match the time memorized for that particular memory position. This method is an algorithm in software with no extra hardware cost. However, this method of counting actuator motor running timing is not accurate. This inaccuracy is caused by various factors including motor start-up, motor speed variation on different seat positions, mechanism gaps, and actuator moving directions.

These factors can cause 20%-30% of memory position shift within the actuator moving whole range. For example, with regard to motor start-up, when the motor starts up, there is a short period of time where the motor is powered up, but not running. If there are several short times for the actuator moving to the memory position, the motor start-up periods add time to the memory position, but the motor is not running. In another example, with regard to motor speed variation, motor speed relates to the load on the actuator (e.g., the heavier the load, the slower the speed). Different people with different weights can make actuator motor either run slow or run fast. In a further example, with regard to motor mechanism gap, the motor mechanism gap needs motor extra running for actuator moving each time. In an additional example, with regard to actuator moving direction, a seat back can go down faster than the seat back can go up (especially with the weight of a user resting on the seat back). All the foregoing (and other issues) could easily cause 20%-30% of memory position shift when the method of counting actuator motor running time is used.

The second method is to monitor an actuator motor encoder while the motor is running. The encoder can be a potentiometer and a Hall effect sensor. These sensors are attached to the actuator motor. When the actuator motor is running, the potentiometer changes the resistance value and the Hall effect sensor sends out a pulse for each motor shaft rotation. The encoders need to be built-in with the motor. The actuator motor with the encoder can run accurately for moving to the memory position but this comes at a high monetary cost. The types of actuators typically used in the furniture industry (i.e., actuator motors without encoders) are very low cost (in the range of around twenty to thirty US dollars) while an actuator motor with a built-in encoder could cost up to one hundred US dollars.

There is a need to create a low-cost and highly-accurate way to operate actuator motors in a reclining seat in order to move the reclining seat to a particular configuration stored within a memory associated with the reclining seat.

Accordingly, there is a need for a system and method for operating actuator motors in a reclining seat that is both low-cost and highly-accurate. There is also a need for a system and method for moving a reclining seat to a position stored in memory that is easier to manufacture, assemble, adjust, and maintain. The present invention satisfies these needs and provides other related advantages.

### SUMMARY

The present invention provides system and method for operating actuator motors in a reclining seat that is both low-cost and highly-accurate. The present invention also provides a system and method for moving a reclining seat to a position stored in memory that is easier to manufacture, assemble, adjust, and maintain.

The system and method for operating actuator motors in a reclining seat uses motor spike pulse counting to provide low cost (e.g., less than five (5) US dollars) and highly accurate movement of portions of the reclining seat to a configuration stored in a memory associated with the reclining seat. The actuator motors are DC brush motors. As the DC motor armature rotates, a voltage spike is generated when the motor brushes move from one commutator segment to the next commutator segment. By counting the commutator voltage spikes, the actuator motor speed and moving distance can be calculated. Commutator voltage spikes are small signals that needs to be amplified and filtered any noise from power supplies or circuitry. The amplified signals can be compared with a DC voltage and input to a microprocessor as pulses, or directly be read by a microprocessor as A/D inputs and processed by software algorithms. The foregoing provides a method for the actuator motor to accurately move portions of the reclining seat to a position stored in the memory associated with the reclining seat.

In accordance with an embodiment of the invention, a system and computer implemented method are disclosed herein for controlling an actuator in a reclining seat. A plurality of actuators are provided in a reclining seat, each actuator moving at least one portion of the reclining seat. Voltage spike pulses are generated as each actuator moves the at least one portion of the reclining seat. Voltage spike pulses of each actuator motor are counted as each actuator moves, and a configuration of the reclining seat is stored in a memory associated with the reclining seat.

This brief summary has been provided so that the nature of the invention may be understood quickly. A more complete understanding of the invention can be obtained by reference to the following detailed description of the preferred embodiments thereof concerning the attached drawings.

### BRIEF DESCRIPTION OF THE DRAWINGS

The foregoing aspects, features and advantages of the present invention will be further appreciated when considered with reference to the following description of exemplary embodiments and accompanying drawings, wherein like reference numerals represent like elements. In describing the exemplary embodiments of the invention illustrated in the drawings, specific terminology may be used for the sake of clarity. However, the aspects of the invention are not intended to be limited to the specific terms used. Likewise, the aspects of the invention are not intended to be limited to specific pictograms used to illustrate various components. The illustrated embodiments are intended to illustrate, but not to limit the invention.

FIG. 1 illustrates a perspective view of an embodiment of a reclining chair in accordance with aspects of the disclosure, with the reclining chair shown in a stowed configuration;

FIG. 2 illustrates another perspective view of FIG. 1, with the reclining chair shown in a deployed configuration;

FIG. 3 illustrates a diagram of a system in accordance with aspects of the disclosure;

FIG. 4 illustrates a flow diagram for actuator processing in accordance with aspects of the disclosure;

FIG. 5 illustrates a flow diagram for main loop in accordance with aspects of the disclosure;

FIGS. 6A-6B illustrate a flow diagram for read motor pulse in accordance with aspects of the disclosure; and

FIGS. 7A-7B illustrate a flow diagram for scan button input in accordance with aspects of the disclosure.

### DETAILED DESCRIPTION

The following detailed description describes the present embodiments with reference to the drawings. In the drawings, reference numbers label elements of the present embodiments. These reference numbers are reproduced below in connection with the discussion of the corresponding drawing features.

It is to be understood that the figures and descriptions of the present invention have been simplified to illustrate elements that are relevant for a clear understanding of the present invention, while eliminating, for the purpose of clarity, many other elements found in charging station systems. Those of ordinary skill in the pertinent arts may recognize that other elements and/or steps are desirable and/or required in implementing one or more embodiments of the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the pertinent arts.

As a preliminary note, any of the embodiments described with reference to the figures may be implemented using software, firmware, hardware (e.g., fixed logic circuitry), manual processing, or a combination of these implementations. The terms “logic,” “module,” “component,” “system” and “functionality,” as used herein, generally represent software, firmware, hardware, or a combination of these elements. For instance, in the case of a software implementation, the terms “logic,” “module,” “component,” “system,” and “functionality” represent program code that performs specified tasks when executed on a processing device or devices (e.g., CPU or CPUs). The program code can be stored in one or more computer readable memory devices.

More generally, the illustrated separation of logic, modules, components, systems, and functionality into distinct units may reflect an actual physical grouping and allocation of software, firmware, and/or hardware, or can correspond to a conceptual allocation of different tasks performed by a single software program, firmware program, and/or hardware unit. The illustrated logic, modules, components, systems, and functionality may be located at a single site (e.g., as implemented by a processing device), or may be distributed over a plurality of locations.

The term “machine-readable media” and the like refers to any kind of non-transitory medium for retaining information in any form, including various kinds of storage devices (magnetic, optical, static, etc.). Machine-readable media also encompasses transitory forms for representing information, including various hardwired and/or wireless links for transmitting the information from one point to another.

The embodiments disclosed herein, may be implemented as a computer process (method), a computing system, or as an article of manufacture, such as a computer program product or non-transitory computer-readable media. The computer program product may be computer storage media, readable by a computer device, and encoding a computer program of instructions for executing a computer process. The computer program product may also be a propagated signal on a carrier, readable by a computing system, and encoding a computer program of instructions for executing a computer process.

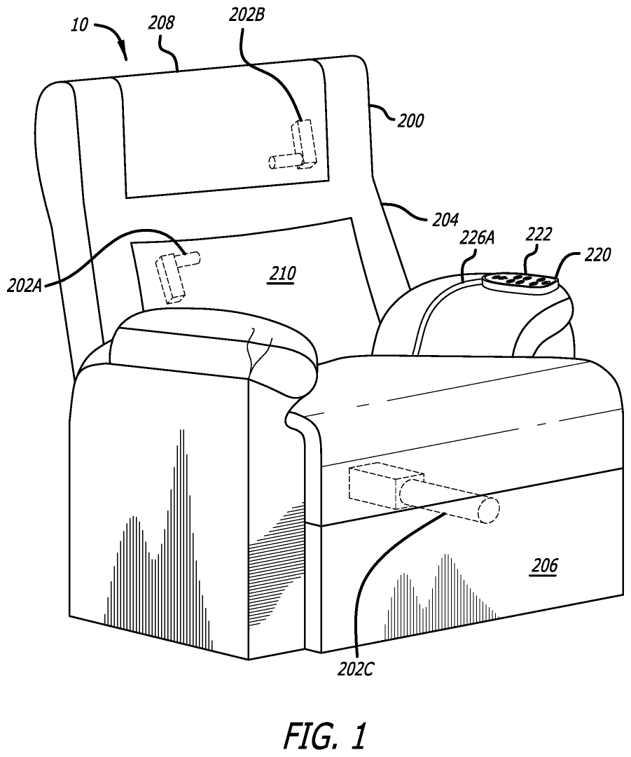

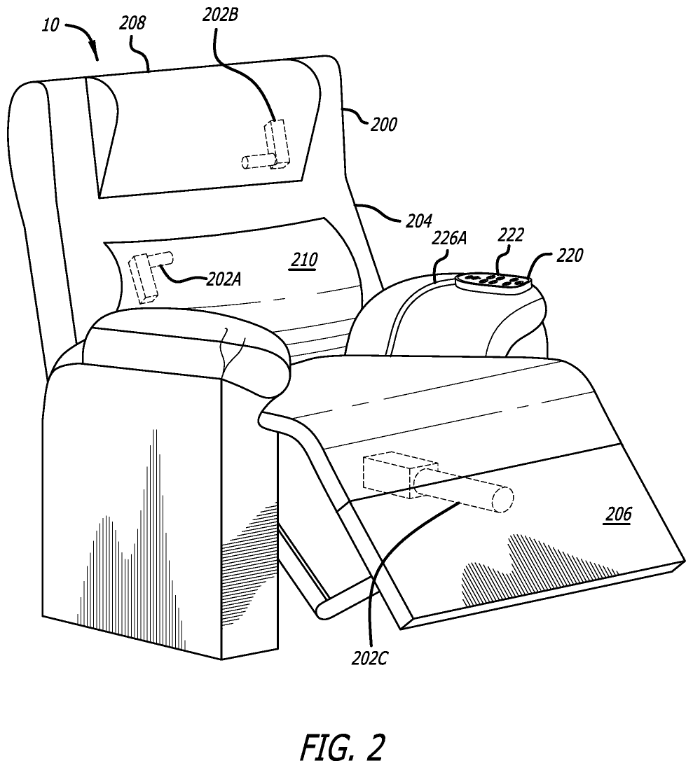

As shown in FIGS. 1-7B for purposes of illustration, an embodiment of the present invention resides in a system 10 and a method 100 for controlling movement of a reclining seat 200 having one or more actuator motors 202A-C.

In accordance with an embodiment of the invention, the reclining seat 200 can be built with one or more actuator motors 202A-C. Each actuator motor 202A-C can move one or more portions of the reclining seat 200 including, without limitation, the seat back 204, the leg rest 206, the head rest 208, the lumbar support 210, as well as lifting/lowering the reclining seat 200 itself (e.g., adjusting the vertical height of reclining seat 200). The actuator motor 202A is the actuator that moves the lumbar support 210, and the actuator motor 202B is the actuator that moves the head rest 208. The same actuator 202C is used to move the seat back 204, and the leg rest 206. An electronically-controlled reclining seat 200 can come with a control wand 220 having buttons 222 for operation of the actuator motors 202A-C in disposed within the reclining seat 200. The control wand 220 may be connected to a harness box 12 that includes a computing device 14 having a microcontroller 224 disposed within the reclining chair 200. The microcontroller 224 has a central processing unit (CPU) or processors with RAM, ROM, and other peripherals. The control wand 220 and harness box 12 may be connected by a cable 226A, 226B carrying signals to the harness box 12. The system 10 further includes an external power adapter (not shown) having a standard power-in plug to an electrical outlet (not shown) (e.g., wall electrical outlet, floor electrical outlet, or the like) and a din-type plug for power to one of the actuators 202A-C (e.g., the din-type plug may be connected to power-in connector on the recline actuator 202C). The external power adapter converts all power 110 Vac-240 Vac to 24 Vdc-29 Vdc for actuator use. The input power is powering the actuators 202A-C and is converted within the harness box 12 to low voltage for all the circuitry in harness box 12 as well as the control wand 220. The power from the external power adapter is going directly to the recline actuator 202C, and along the actuator cable 228 to the harness box 12. The actuator 202C The cable 228 for the actuator 202C has four (4) wires. Two (2) of these wires are used to passing the external power to a printed circuit board located in the harness box 12. These two (2) wires are soldered to a portion of the printed circuit board for 29 Vdc power input. The cables 226A, 226B are matingly engage each other via quick connect/disconnect connectors (e.g., male/female connectors). One end of the cable 226B may be fixed in position somewhere on the reclining seat 200 out of view of the user. In the alternative, the control wand 220 and the harness box 12 may be wirelessly connected. The harness box 12 and motor actuators 202A-C are connected by cables 228. In the alternative, a bluetooth module may be provided for communicating with tablets, smartphones, and computers. Power circuitry within the harness box 12 convert 29V input power to 5V for circuitry use, and 5V is converted to 3.3V for use by the microcontroller 224. The harness box 12 further includes motor voltage spike reading circuitry (not shown). The recline actuator 202C has a cable with four (4) wires connected to the harness box 12 (e.g., two (2) wires for 29V power input which connected to a solder pad on printed circuit board in harness box 12, and the other two (2) wires for the recline actuator 202C are soldered to another solder pad on the printed circuit board in the harness box 12. The cable 226B is an eight (8) wire cable and the 8 wires are soldered to other solder pad on the printed circuit board in the harness box 12. The lumbar actuator 202A and the head rest actuator 202B only have a two (2) wire cable 228 each. The two (2) wire cable 228 for the lumbar actuator 202A goes to an additional solder pad on the printed circuit board in harness box 12 and the two (2) wire cables 228 for the head rest actuator 202B goes to still another solder pad on printed circuit board in harness box 12.

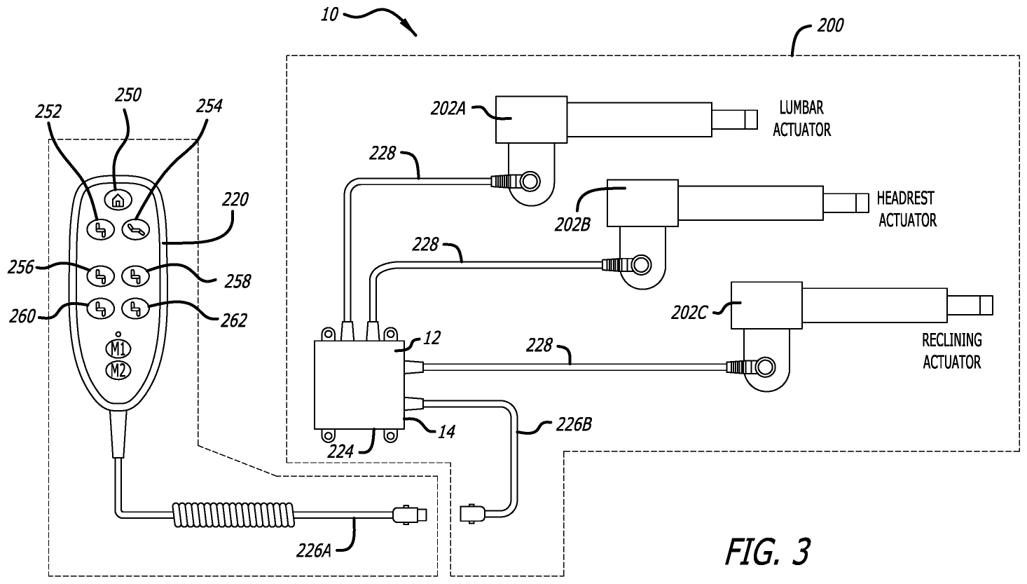

The control wand 220 can include buttons 222 for moving one or more portions of the reclining seat 200. These buttons 222 can include, without limitation, a back up/down button(s), a leg up/down button(s), a head up/down button(s), a lumbar out/in button(s), and a recline/return button(s). In the industry, when a reclining seat 200 is in a fully-closed position, that position is commonly referred to as the “Home” position. As seen in FIG. 3, the buttons 22 of the control wand 220 include a “Home” button 250 which bring the seat back 204, leg rest 206, and head rest 208 to a home position (i.e., an initial position) with the seat back 204 straight up (i.e., in a generally vertical position), leg rest 206 straight down (i.e., in a generally vertical position), and the head rest 208 and the lumbar support 210 all the way backward. Another button 252 is the “Return” button which moves the seat back 204, and the leg rest 206 from whatever position they are in to a fully closed position (configuration). Another button 254 is the “Recline” button which moves the seat back 204, and the leg rest 206 from whatever position they are in to a fully reclined/open position (configuration). The buttons 252, 254 need to be pressed and held in a pressed position for continuous “Return” or “Recline.” The buttons 252, 254 move the seat back 204, and the leg rest 206 with the same actuator 202C.

The button 256 moves the head rest 208 to a stowed position while the button 258 moves the head rest 208 to a deployed position. A button 260 moves the lumbar support 210 to a stowed position while a button 262 moves the lumbar support 210 to a deployed position . The control wand 220 can also include one or more memory buttons M1, M2. Each of the memory buttons M1, M2 stores a particular deployed configuration of the reclining seat 200. These memory buttons M1, M2 are used as part of the process of the processing ‘memorizing’ the favorite seat position(s) of one or more users (i.e., storing the position of a favorite seat position in a memory). Upon pressing a particular memory button M1, M2, one or more of the actuator motors 202A-C move the reclining seat 200 into the position stored in a memory of the computing device 12. Alternatively, instead of a control wand 220, various other control options include, without limitation, a tablet device, a smartphone, or the like.

FIGS. 1-3 illustrate an embodiment of a system 10 in which the features described above may be implemented. It should not be considered as limiting the scope of the disclosure or usefulness of the features described herein. In this example, the system 10 can include a harness box 12 that includes a computing device 14 having one or more processors (CPUs) 224, memory, and other components typically present in general purpose computing devices. The memory of the computing device 14 can store information accessible by the one or more processors 224, including instructions that can be executed by the one or more processors 224. The memory can also include data that can be retrieved, manipulated or stored by the one or more processors 224. The memory can be of any non-transitory type capable of storing information accessible by the one or more processors, such as a solid state hard drive (SSD), disk based hard-drive, memory card, ROM, RAM, DVD, CD-ROM, Blu-Ray, write-capable, and read-only memories. The data can comprise any information sufficient to identify relevant information including, but not limited to, numbers, descriptive text, proprietary codes, pointers, references to data stored in other memories, or information that is used by a function to calculate the relevant data.

The instructions can be any set of instructions to be executed directly, such as machine code, or indirectly, such as scripts, by the one or more processors. In that regard, the terms “instructions,” “application,” “steps,” and “programs” can be used interchangeably herein. The instructions can be stored in a proprietary computer language, object code format for direct processing by the one or more processors, or in any other computing device language including scripts or collections of independent source code modules that are interpreted on demand or compiled in advance. Functions, methods, and routines of the instructions are explained in more detail below. Based on the instructions, the processor(s) 224 may then transmit signals to one or more actuator motors 202A-C.

Data may be retrieved, stored or modified by the one or more processors 224 in accordance with the instructions. For instance, although the subject matter described herein is not limited by any particular data structure, the data can be stored in computer registers, in a relational or non-relational database as a table having many different fields and records, or XML documents.

The computing device 14 may include a compiler which may compile the data and instructions from a first format into a device-readable format. For example, the compiler may receive instructions in a proprietary computer language or a programming language (e.g., Java, C#, C, C++, Basic, Fortran, etc.) and convert the instructions into a device-readable format such as, but not limited to, binary values, ASCII, or Unicode.

The one or more processors 224 can be any conventional processors, such as a commercially available CPU produced by INTEL, ARM, AMD, or other brands. Alternatively, the processors can be dedicated components such as an application specific integrated circuit (“ASIC”), a system on chip (“SOC”), field programmable gate array (FPGA), or other hardware-based processor.

Although FIG. 3 functionally illustrates the harness box 12 including a computing device 14 having a microcontroller including one or more processors 224 (memory, and other components are not shown) as being within the same housing, the one or more processors 224, memory, and other components can actually comprise multiple processors, memories, and other components that may or may not be stored within the same physical housing. Accordingly, references to a processor, memory, or other elements will be understood to include references to more than one processors, memories, or other elements that may or may not operate in parallel. Additionally, the computing device 14 can be comprised of more than one computing device.

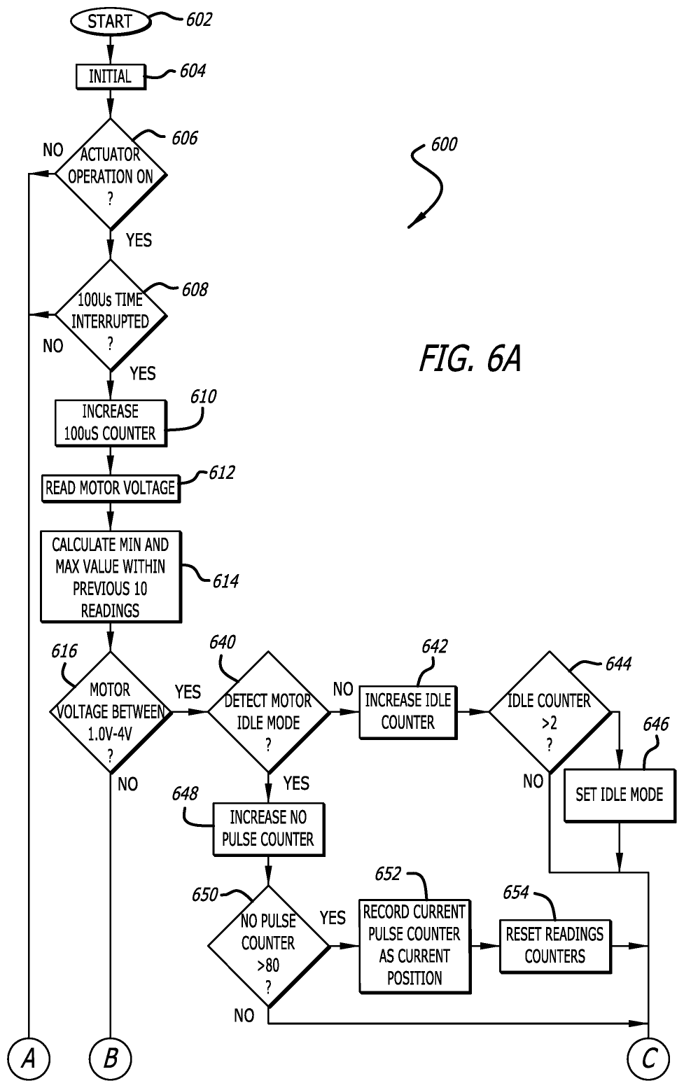

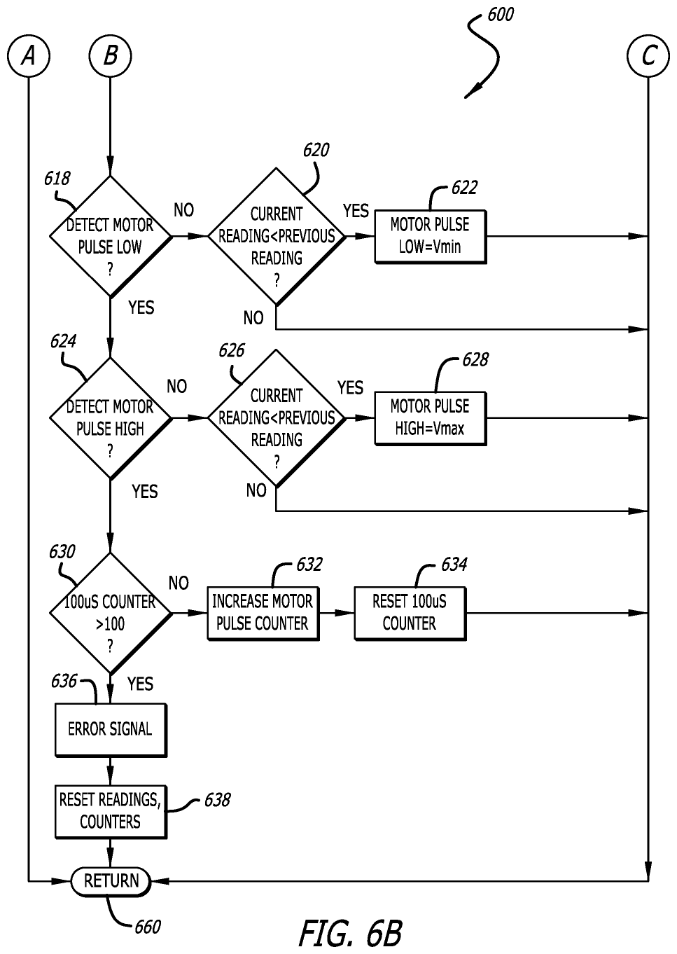

In accordance with an embodiment of the present invention, the system 10 and method 100 disclosed herein for operating actuator motors in a reclining seat uses motor spike pulse counting to provide low cost (e.g., less than five US dollars) and highly accurate movement of portions of the reclining seat to a configuration stored in a memory associated with the reclining seat. The actuator motors 202A-C are DC brush motors. As the DC motor armature rotates, a commutator voltage spike is generated when the motor brushes move from one commutator segment to the next commutator segment. By counting the commutator voltage spikes, the actuator motor speed and moving distance can be calculated. The commutator voltage spikes are counted via software in the microprocessor monitoring the motor voltage to recognize voltage spikes via an algorithm (see FIGS. 6A-6B). The software executed by the microprocessor 224 also scans inputs from the buttons. The software executed by the microprocessor 224 also analyzes the button inputs decide the motor direction (i.e., forward or backward movement of the actuator) and the voltage spikes counting decides motor speed and distance. The foregoing provides the system 10 and method 100 for the actuator motor 202A-C to accurately move portions of the reclining seat 200 to a position stored in the memory associated with the reclining seat 200.

The commutator voltage spikes are small signals that need to be amplified and filtered to remove any signal noise from power supplies or circuitry. For example, most commutator voltage spikes are measured in 10-100 millivolt and need to be amplified to 1-5 volts. The amplified and filtered signals are compared with a DC voltage, and then input to a microprocessor 224 as pulses, or directly be read by a microprocessor 224 of the reclining seat 200 as analog-to-digital (A/D) inputs. The microprocessor 224 then executes software algorithms stored within the memory associated with the reclining seat 200.

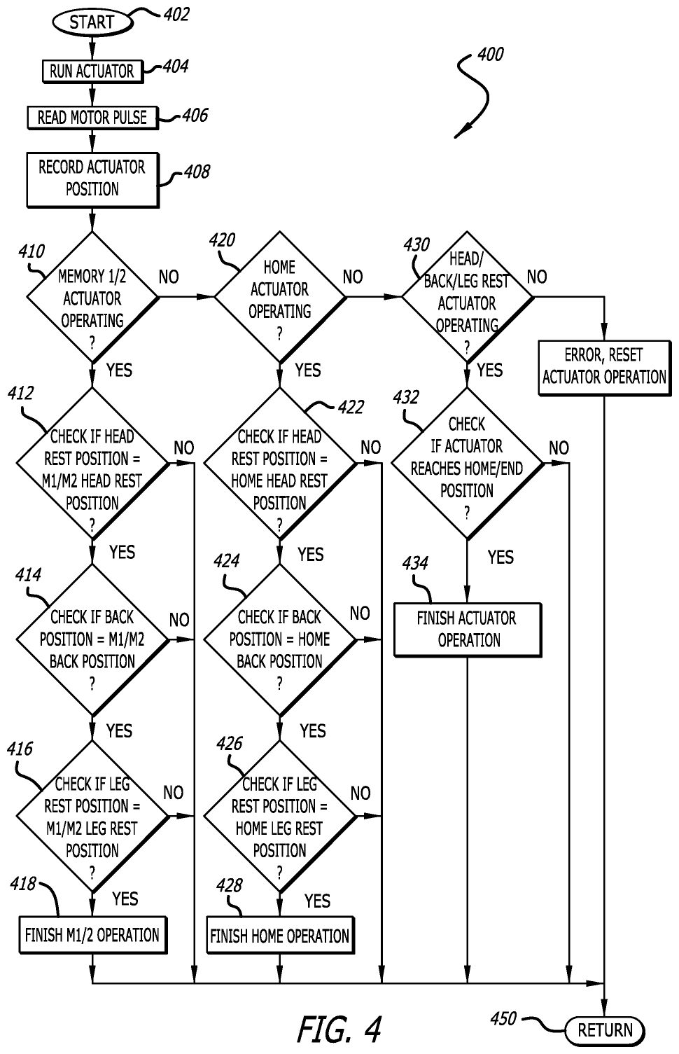

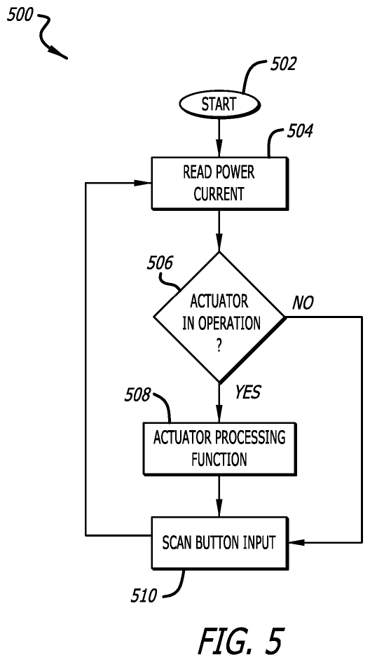

FIGS. 4 illustrates a process flow diagram for actuator processing 400 in accordance with the system 10 and method 100 disclosed herein. In step 402, the process starts. In step 404, the actuator is run. In step 406, the motor pulse is read. In step 408, the actuator position is recorded. In step 410, if a M1/M2 actuator is determined to be operating, then the process proceeds to step 412 where a check is performed to determine if the head rest position is the same as the M1/M2 head rest position. If the head rest position is not the same as the M1/M2 head rest position, the process proceeds to step 450 to Return 450. The actuator processing 400 is the actuator processing function 508 of FIG. 5. It exits actuator processing 400, returns back to the main loop 500 (see below) and will run “Scan button input” function 510. It will go into the actuator processing 400 in next loop. If the head rest position is the same as the M1/M2 head rest position, the process proceeds to step 414 where a check is performed to determine if the back rest position is the same as the M1/M2 back rest position. If the back rest position is not the same as the M1/M2 back rest position, the process proceeds to step 450 to Return. If the back rest position is the same as the M1/M2 back rest position, the process proceeds to step 416 where a check is performed to determine if the leg rest position is the same as the M1/M2 leg rest position. If the leg rest position is not the same as the M1/M2 leg rest position, the process proceeds to step 450 to Return. If the leg rest position is the same as the M1/M2 leg rest position, the process proceeds to step 418 where a command is executed finishing M1/M2 operation, and the process proceeds to step 450 to Return.

In step 410, if a M1/M2 actuator is determined to not be operating, then the process proceeds to step 420 where it is determined if the ‘home’ actuator is operating. In step 420, if a ‘home’ actuator is determined to be operating, then the process proceeds to step 422 where a check is performed to determine if the head rest position is the same as the ‘home’ head rest position. If the head rest position is not the same as the ‘home’ head rest position, the process proceeds to step 450 to Return. If the head rest position is the same as the ‘home’ head rest position, the process proceeds to step 424 where a check is performed to determine if the back rest position is the same as the ‘home’ back rest position. If the back rest position is not the same as the ‘home’ back rest position, the process proceeds to step 450 to Return. If the back rest position is the same as the ‘home’ back rest position, the process proceeds to step 426 where a check is performed to determine if the leg rest position is the same as the ‘home’ leg rest position. If the leg rest position is not the same as the ‘home’ leg rest position, the process proceeds to step 450 to Return. If the leg rest position is the same as the ‘home’ leg rest position, the process proceeds to step 428 where a command is executed finishing ‘home’ operation, and the process proceeds to step 450 to Return.

In step 420, if a home actuator is determined to not be operating, then the process proceeds to step 430 where it is determined if the head/back/leg rest actuator is operating. In step 430, if a head/back/leg rest actuator is determined to be operating, then the process proceeds to step 432 where a check is performed to determine if the actuator reaches home/end position. If the actuator does not reach home/end position, the process proceeds to step 450 to Return. If the actuator reaches home/end position, the process proceeds to step 434 where a command is executed to finish actuator operation, and the process then proceeds to step 450 to Return.

In step 430, if it is determined that the head/back/leg rest actuator is not operating, then the process proceeds to step 440 where an error message is generated, actuator operation is reset, and the process then proceeds to step 450 to Return.

FIG. 5 illustrates a process flow diagram for main loop 500 in accordance with the system 10 and method 100 disclosed herein. In step 502, the process starts. In step 504, power current is read and, proceeding to step 506, it is determined if the actuator is in operation. If the actuator is in operation, the process proceeds to step 508, where the actuator process function is performed. Once the actuator process function is performed, the process proceeds to step 510 where button input is scanned, which proceeds back to step 504 where power current is read. If it is determined in step 506 that the actuator is not in operation, the process proceeds to step 510,where button input is scanned, and then proceeds back to step 504 where power current is read, and the process 500 continues from there.

FIGS. 6A-6B illustrate a flow diagram for read motor pulse in accordance with the system 10 and method 100 disclosed herein. In step 602, the process starts, and proceeds to step 604. In step 604, software is initialized (e.g., Initial 604 is a process in software to reset the variables and counters used in software to recognize motor voltage spike(s)) and, proceeding to step 606, it is determined if the actuators are on (i.e., in operation). If the actuators are not in operation, the process proceeds to step 660 to Return. The processing 600 is “Read motor pulse” function 406 in actuator processing 400. It exits processing, returns to actuator processing 400 and will run function 408 (i.e., Record Actuator Position). If the actuators 202 are in operation, the process proceeds to step 608, where it is determined if 100 microsecond time is interrupted (e.g., function 608 starts every 100 microsecond, and the 100 microsecond period is generated by a timer interrupt function of the microprocessor). If the 100 microsecond time is not interrupted, the process proceeds to step 660 to Return. If the 100 microsecond time is interrupted, the process proceeds to step 610 where the 100 microsecond counter is increased, which proceeds to step 612 where motor voltage is read. The process then proceeds to step 614 where maximum and minimum values within the previous ten (10) readings are calculated. The process 600 then proceeds to step 616 where it is determined if motor voltage is about one (1.0) to four (4.0) volts.

If motor voltage is not about one (1.0) to four (4.0) volts, the process 600 proceeds to step 618 where it is determined if a low motor pulse is detected (e.g., the motor voltage spike is amplified in 1-4 volt range, and in triangular wave form where the low motor pulse is referring to the lower portion of the triangular wave form).

If a low motor pulse is not detected, the process 600 proceeds to step 620 where it is determined if the current reading is greater than the previous reading (e.g., “current reading” refers to the reading of the motor pulse at the current time). If the current reading is not less than the previous reading, the process 600 proceeds to step 660 to Return. If the current reading is less than the previous reading, the process 600 proceeds to step 622 where the low motor pulse is set as the minimum voltage (V.), and the process 600 proceeds to step 660 to Return.

If a low motor pulse is detected, the process 600 proceeds to step 624 where it is determined if a high motor pulse is detected (e.g., the motor voltage spike is amplified in 1-4 volt range, and in triangular wave form where the high pulse is refer to the higher portion of the triangular wave form). The software needs to trace the voltage spike from low to high and high to low as a complete spike shape to recognize a pulse. If a high motor pulse is not detected, the process 600 proceeds to step 626 where it is determined if the current reading is less than the previous reading (e.g., “current reading” refers to the reading of the motor pulse at the current time). If the current reading is not less than the previous reading, the process 600 proceeds to step 660 to Return. If the current reading is less than the previous reading, the process 600 proceeds to step 628 where the high motor pulse is set as the maximum voltage (Vmax), and the process 600 proceeds to step 660 to Return.

If a high motor pulse is detected, the process 600 proceeds to step 630 where it is determined if the 100 microsecond counter is over 100 counts (e.g., the software limits the motor voltage spikes in 10 milliseconds (100×100 microseconds)). If the 100 microsecond counter is over 100, the process 600 proceeds to step 632 where the motor pulse counter is increased by one (1), and the process 600 then proceeds to step 634 where the 100 microsecond counter is reset. After that, the process 600 proceeds to step 660 to Return.

If the 100 microsecond counter is not over 100, the process 600 proceeds to step 636 where an error signal is generated, and the process 600 then proceeds to step 638 where the readings and counters are reset. After that, the process 600 proceeds to step 660 to Return.

If it is determined at step 616 that motor voltage is about one (1.0) to four (4.0) volts, the process 600 proceeds to step 640 where it is determined if a motor idle mode is detected. Idle mode is the actuator 202 being in standby, and not running. It is the case of actuators 202 moving to the end of each direction. There are two limit switches, with a switch located on each of the two ends of an actuator 202. These limit switches turn off actuator power as protection when the actuator 202 is moving towards an end position. The software needs to detect if an actuator 202 is moving to one of the ends and the actuator 202 stops there as in “idle mode” or “stand by” mode. If it is determined that a motor idle mode is not detected, the process proceeds to step 642 where an idle counter is increased, and then to step 644 where it is determined if the idle counter is greater than two (2) counts (e.g., if the software detects the actuator motor 202 not running 2 times/counts, it sets the actuator 202 in idle mode). If the idle counter is not greater than two (2), the process proceeds to step 660 to Return. If the idle counter is greater than two (2), the process 600 proceeds to step 646 where idle mode is set, and the process 600 proceeds to step 660 to Return.

If it is determined that a motor idle mode is detected, the process proceeds to step 648 where a “no pulse” counter is increased, and then to step 650 where it is determined if the “no pulse” counter is greater than eighty (80) counts (e.g., eighty (80) counts is eight (8) milliseconds, which is a safe period to recognize motor stop without noise interference). If the “no pulse” counter is not greater than eighty (80), the process proceeds to step 660 to Return. If the “no pulse” counter is greater than eighty (80), the process 600 proceeds to step 652 where current pulse counter is recorded as the current position, and the process 600 proceeds to step 654 where the readings counters are reset, and then on to step 660 to Return.

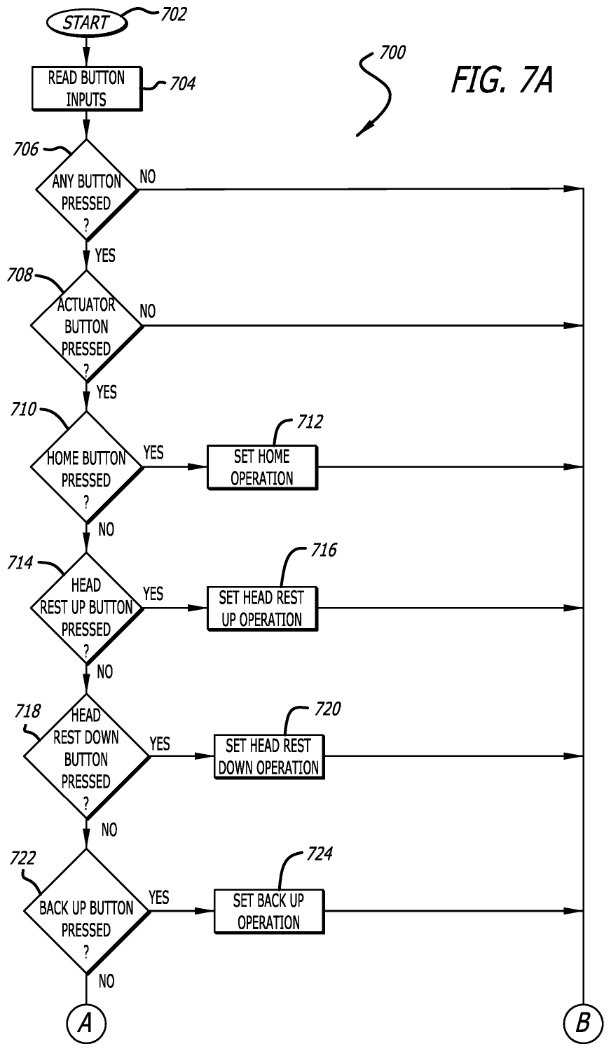

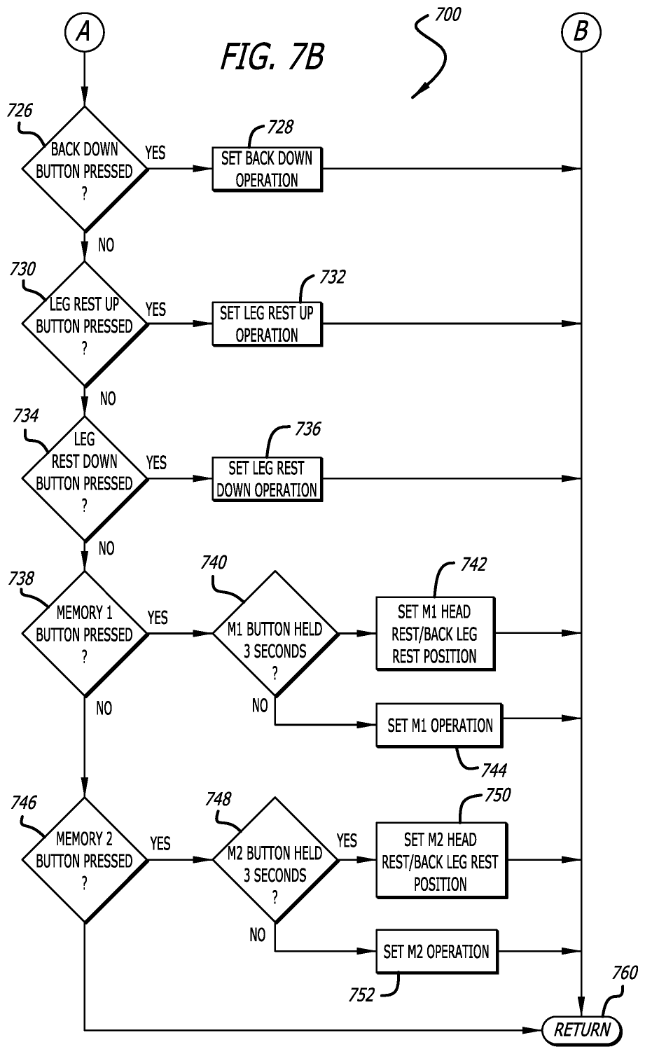

FIGS. 7A-7B illustrate a flow diagram for scan button input in accordance with the system 10 and method 100 disclosed herein. In step 702, the process starts, and proceeds to step 704. In step 704, button inputs are read and, proceeding to step 706, it is determined if any button of the control wand 220 has been pressed. If no buttons have been pressed, the process 700 proceeds to step 760 and Ends. If it is determined in step 706 that any button of the control wand 220 has been pressed, the process 700 proceeds to step 708 where it is determined if any actuator button of the control wand 220 has been pressed. If no actuator button has been pressed, the process 700 proceeds to step 760 and Ends. If an actuator button has been pressed, the process 700 proceeds to step 710 where it is determined if the Home button has been pressed.

If the Home button has been pressed, the process 700 proceeds to step 712 where Home Operation is set, and the process proceeds to step 760 and Returns.

If the Home Button has not been pressed, the process 700 proceeds to step 714 where it is determined if the Head Rest Up button has been pressed.

If the Head Rest Up button has been pressed, the process 700 proceeds to step 716 where Head Rest Up Operation is set, and the process proceeds to step 760 and Returns.

If the Head Rest Up Button has not been pressed, the process 700 proceeds to step 718 where it is determined if the Head Rest Down button has been pressed.

If the Head Rest Down button has been pressed, the process 700 proceeds to step 720 where Head Rest Down Operation is set, and the process proceeds to step 760 and Returns.

If the Head Rest Down Button has not been pressed, the process 700 proceeds to step 722 where it is determined if the Back Up button has been pressed.

If the Back Up button has been pressed, the process 700 proceeds to step 724 where Back Up Operation is set, and the process proceeds to step 760 and Returns.

If the Back Up Button has not been pressed, the process 700 proceeds to step 726 where it is determined if the Back Down button has been pressed.

If the Back Down button has been pressed, the process 700 proceeds to step 728 where Back Down Operation is set, and the process proceeds to step 760 and Returns.

If the Back Down Button has not been pressed, the process 700 proceeds to step 730 where it is determined if the Leg Rest Up button has been pressed.

If the Leg Rest Up button has been pressed, the process 700 proceeds to step 732 where Leg Rest Up Operation is set, and the process proceeds to step 760 and Returns.

If the Leg Rest Up Button has not been pressed, the process 700 proceeds to step 734 where it is determined if the Leg Rest Down button has been pressed.

If the Leg Rest Down button has been pressed, the process 700 proceeds to step 736 where Leg Rest Down Operation is set, and the process proceeds to step 760 and Returns.

If the Leg Rest Down Button has not been pressed, the process 700 proceeds to step 738 where it is determined if the Memory 1 (M1) button has been pressed.

If the Memory 1 button has been pressed, the process 700 proceeds to step 740 where it is determined if the M1 Button has been held for three (3) seconds. If the M1 button has been held for three (3) seconds, the process 700 proceeds to step 742 where M1 Head Rest/Back/Leg Rest Position is set, and the process proceeds to step 760 and Returns. If the M1 button has not been held for three (3) seconds, the process 700 proceeds to step 744 where M1 Operation is set, and the process proceeds to step 760 and Returns.

If the M1 Button has not been pressed, the process 700 proceeds to step 746 where it is determined if the Memory 2 (M2) button has been pressed.

If the Memory 2 button has been pressed, the process 700 proceeds to step 748 where it is determined if the M2 Button has been held for three (3) seconds. If the M2 button has been held for three (3) seconds, the process 700 proceeds to step 750 where M2 Head Rest/Back/Leg Rest Position is set, and the process proceeds to step 760 and Returns. If the M2 button has not been held for three (3) seconds, the process 700 proceeds to step 752 where M2 Operation is set, and the process proceeds to step 760 and Returns. If the M2 button has not been pressed, the software shall go to Return 760 in case of ‘No’. Processing 700 is the “Scan button input” 510 in FIG. 5. The software exits process 700 and returns back to the main loop 500.

The systems and processes described above are applicable and useful in the upcoming cloud computing environment as a reclining seat 200 may be part of a “smart home” system where various devices (e.g., televisions, refrigerators, dishwashers, lamps, etc.) are controlled by a “central” control unit which may or may not be fully located in the home itself or in the cloud environment. Cloud computing pertains to computing capability that provides an abstraction between the computing resource and its underlying technical architecture (e.g., servers, storage, networks), enabling convenient, on-demand network access to a shared pool of configurable computing resources that can be rapidly provisioned and released with minimal management effort or service provider interaction. The term “cloud” is intended to refer to the Internet and cloud computing allows shared resources, for example, software and information, to be available, on-demand, like a public utility. Typical cloud computing providers deliver common business applications online, which are accessed from another web service or software like a web browser, while the software and data are stored remotely on servers. The cloud computing architecture uses a layered approach for providing application services. The lowest layer is an application layer that is executed on client computers. In this example, the application allows a client to access cloud storage. Above the application layer is a cloud platform and cloud infrastructure, including a “server” layer that includes hardware and computer software designed for cloud-specific services.

The systems and processes described above are also applicable and useful in connection with electric seats (aka power seats) in automobiles. Electric seats in automobiles use motor actuators to change the position of various portions (e.g., seat portion, back portion, head rest portion, etc.) of an electric seat. Similar to a reclining chair, an automotive seat may include a number of actuators that control the respective positions of the various portions of the electric seat including, but not limited to, the vertical position, tilt, horizontal position, etc.). Buttons generally located on the sides of the electric seats are used to control the positions of the various portions of a particular seat. The electric seat may include one or more memory buttons that can be used by a user similar to the manner described above with regard to the reclining seat 200. Memory buttons could alternatively be located anywhere in the automobile, including as part of a graphical user interface or the like used to control various features in the automobile including, but not limited to, radio, temperature controls or the like. The systems and processes described above could be incorporated directly incorporated into the electric seat itself or into the computer system of the automobile (e.g., the electric seat may be connected to the automobile's computer system, and a preferred position of a driver or passenger electric seat stored in the memory of the automobile's computer system).

Unless expressly stated otherwise, the foregoing alternative examples are not mutually exclusive, but may be implemented in various combinations to achieve unique advantages. As these and other variations and combinations of the features discussed above can be utilized without departing from the subject matter defined by the claims, the foregoing description of the embodiments should be taken by way of illustration rather than by way of limitation of the subject matter defined by the claims. As an example, the preceding operations do not have to be performed in the precise order described above. Rather, various steps can be handled in a different order, such as reversed, or simultaneously. Steps can also be omitted unless otherwise stated. In addition, the provision of the examples described herein, as well as clauses phrased as “such as,” “including” and the like, should not be interpreted as limiting the subject matter of the claims to the specific examples; rather, the examples are intended to illustrate only one of many possible embodiments. Further, the same reference numbers in different drawings can identify the same or similar elements.

In addition, the claimed invention is not limited in size and may be constructed in various sizes in which the same or similar principles of operation as described above would apply. Furthermore, the figures (and various components shown therein) of the specification are not to be construed as drawn to scale.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

The use of the expression “at least” or “at least one” suggests the use of one or more elements or ingredients or quantities, as the use may be in the embodiment of the disclosure to achieve one or more of the desired objects or results.

The numerical values mentioned for the various physical parameters, dimensions or quantities are only approximations and it is envisaged that the values higher/lower than the numerical values assigned to the parameters, dimensions or quantities fall within the scope of the disclosure, unless there is a statement in the specification specific to the contrary.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially relative terms, such as “front,” “rear,” “left,” “right,” “inner,” “outer,” “beneath”, “below”, “lower”, “above”, “upper”, “horizontal”, “vertical”, “lateral”, “longitudinal” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The above description presents the best mode contemplated for carrying out the present invention, and of the manner and process of making and using it, in such full, clear, concise, and exact terms as to enable any person skilled in the art to which it pertains to make and use this invention. This invention is, however, susceptible to modifications and alternate constructions from that discussed above that are fully equivalent. Moreover, features described in connection with one embodiment of the invention may be used in conjunction with other embodiments, even if not explicitly stated above. Consequently, this invention is not limited to the particular embodiments disclosed. On the contrary, this invention covers all modifications and alternate constructions coming within the spirit and scope of the invention as generally expressed by the following claims, which particularly point out and distinctly claim the subject matter of the invention.

What is claimed is:

1. A computer implemented method for controlling an actuator in a reclining seat, the method comprising:
providing a plurality of actuators in a reclining seat, each actuator moving at least one portion of the reclining seat;
generating voltage spike pulses as each actuator moves the at least one portion of the reclining seat;
counting voltage spike pulses of each actuator motor as each actuator moves; and
storing a configuration of the reclining seat in a memory associated with the reclining seat.

2. The method of the claim 1, further comprising moving the at least one portion of the reclining seat to the stored configuration.

3. The method of claim 1, wherein counting voltage spike pulses further comprises calculating actuator motor speed and moving distance.

4. The method of claim 1, further comprising amplifying voltage spike pulses to remove signal noise.

5. The method of claim 4, wherein amplifying voltage spike pulses further comprises comparing the amplified voltage spike pulse with a DC voltage.

6. The method of claim 1, further comprising filtering voltage spike pulses to remove signal noise.

7. The method of claim 6, wherein filtering voltage spike pulses further comprises comparing the filtered voltage spike pulse with a DC voltage.

8. The method of claim 1, further comprising inputting the voltage spike pulses to a microprocessor associated with the reclining seat.

9. The method of claim 1, further comprising reading the voltage spike pulses as analog-to-digital inputs into a microprocessor associated with the reclining seat.

10. A system for controlling an actuator in a reclining seat, the system comprising: one or more computing devices; a plurality of actuators in a reclining seat, each actuator moving at least one portion of the reclining seat; and
a memory storing instructions, the instructions executable by the one or more computing devices;
wherein the instructions comprise:
generating voltage spike pulses as each actuator moves the at least one portion of the reclining seat;
counting voltage spike pulses of each actuator motor as each actuator moves; and
storing a configuration of the reclining seat in a memory associated with the reclining seat.

11. A non-transitory computer-readable medium storing instructions that, when executed by one or more processors, cause the one or more processors to perform the steps of:
generating voltage spike pulses as each actuator of a plurality of actuators in a
reclining seat moves at least one portion of the reclining seat;
counting voltage spike pulses of each actuator as each actuator moves; and
storing a configuration of the reclining seat in a memory associated with the reclining seat.
